(19) United States
(12) Patent Application Publication
(10) Pub. No.: US 2024/0345383 A1
(43) Pub. Date: Oct. 17, 2024

(54) MEMS Multiple Degree of Freedom Piezoelectric Actuator

(71) Applicant: MEMS DRIVE (NANJING) CO., LTD., NANJING (CN)

(72) Inventors: Xiaolei Liu, South Pasadena, CA (US); Guiqin Wang, Arcadia, CA (US)

(21) Appl. No.: 18/393,007

(22) Filed: Dec. 21, 2023

Related U.S. Application Data
(60) Provisional application No. 63/495,721, filed on Apr. 12, 2023.

(51) Int. Cl. G02B 26/08; H02N 2/02; H02N 2/06; H04N 23/54

(52) U.S. Cl. CPC G02B 26/0858; H02N 2/028; H02N 2/062; H04N 23/54; H04N 23/687

(57) ABSTRACT

A MEMS imaging actuator assembly includes: a first structural assembly; a second structural assembly; and a tip-tilt displacement assembly, configured to position the first structural assembly with respect to the second structural assembly, including: one or more multi-morphic thin film actuator assemblies, and one or more motion control assemblies; wherein one of the structural assemblies is configured to mount an optical device.

### RELATED CASE(S)

This application claims the benefit of U.S. Provisional Application No. 63/495,721 filed on 12 Apr. 2023; the contents of which are incorporated herein by reference.

### TECHNICAL FIELD

This disclosure relates to actuators in general and, more particularly, to miniaturized MEMS actuators configured for use within camera packages.

### BACKGROUND

As is known in the art, actuators may be used to convert electronic signals into mechanical motion. In many applications such as e.g., portable devices, imaging-related devices, telecommunications components, and medical instruments, it may be beneficial for miniature actuators to fit within the small size, low power, and cost constraints of these application.

Micro-electrical-mechanical system (MEMS) technology is the technology that in its most general form may be defined as miniaturized mechanical and electro-mechanical elements that are made using the techniques of microfabrication. The critical dimensions of MEMS devices may vary from well below one micron to several millimeters. In general, MEMS actuators are more compact than conventional actuators, and they consume less power.

### Summary of Disclosure

In one implementation, a MEMS imaging actuator assembly includes: a first structural assembly; a second structural assembly; and a tip-tilt displacement assembly, configured to position the first structural assembly with respect to the second structural assembly, including: one or more multi-morphic thin film actuator assemblies, and one or more motion control assemblies; wherein one of the structural assemblies is configured to mount an optical device.

One or more of the following features may be included. The first structural assembly may be rigidly affixed and the second structural assembly may be configured to be displaceable by the tip-tilt displacement assembly with respect to the first structural assembly. The second structural assembly may be rigidly affixed and the first structural assembly may be configured to be displaceable by the tip-tilt displacement assembly with respect to the second structural assembly. The optical device may be a mirror assembly. The optical device may be an image sensor assembly. The first structural assembly may include: one or more embedded snubber assemblies configured to interface with the second structural assembly and limit in-plane movement of the first structural assembly. An outer frame assembly may be positioned proximate the second structural assembly. One or more electrically conductive flexures may be configured to electrically couple the outer frame assembly and the second structural assembly. The one or more multi-morphic thin film actuator assemblies may include: a piezoelectric layer. The one or more multi-morphic thin film actuator assemblies may include: one or more electrodes positioned proximate the piezoelectric layer. The one or more multi-morphic thin film actuator assemblies may include: a structural layer. One of the structural assemblies may include: one or more glue pads for affixing the optical device. The tip-tilt displacement assembly may be configured to allow rotation of the optical device around two axes. The MEMS imaging actuator may be configured to effectuate one or more of OIS functionality and autofocus functionality. A feedback loop may be configured to process feedback signals that are indicative of a change in dielectric constant of a piezoelectric layer within the one or more multi-morphic thin film actuator assemblies.

In another implementation, a MEMS imaging actuator assembly includes: a first structural assembly; a second structural assembly; and a tip-tilt displacement assembly, configured to position the first structural assembly with respect to the second structural assembly, including: one or more multi-morphic thin film actuator assemblies, and one or more motion control assemblies; wherein one of the structural assemblies is configured to mount an optical device; and wherein the optical device is a mirror assembly.

One or more of the following features may be included. The first structural assembly may be rigidly affixed and the second structural assembly may be configured to be displaceable by the tip-tilt displacement assembly with respect to the first structural assembly. The second structural assembly may be rigidly affixed and the first structural assembly may be configured to be displaceable by the tip-tilt displacement assembly with respect to the second structural assembly. The first structural assembly may include: one or more embedded snubber assemblies configured to interface with the second structural assembly and limit in-plane movement of the first structural assembly. A feedback loop may be configured to process feedback signals that are indicative of a change in dielectric constant of a piezoelectric layer within the one or more multi-morphic thin film actuator assemblies.

In one implementation, a MEMS imaging actuator assembly includes: a first structural assembly; a second structural assembly; and one or more embedded snubber assemblies configured to interface with the second structural assembly and limit in-plane movement of the first structural assembly; a tip-tilt displacement assembly, configured to position the first structural assembly with respect to the second structural assembly, including: one or more multi-morphic thin film actuator assemblies, and one or more motion control assemblies; wherein one of the structural assemblies is configured to mount an optical device; and wherein the optical device is a mirror assembly.

One or more of the following features may be included. The first structural assembly may be rigidly affixed and the second structural assembly may be configured to be displaceable by the tip-tilt displacement assembly with respect to the first structural assembly. The second structural assembly may be rigidly affixed and the first structural assembly may be configured to be displaceable by the tip-tilt displacement assembly with respect to the second structural assembly. An outer frame assembly may be positioned proximate the second structural assembly. One or more electrically conductive flexures may be configured to electrically couple the outer frame assembly and the second structural assembly. The one or more multi-morphic thin film actuator assemblies may include: a piezoelectric layer; one or more electrodes positioned proximate the piezoelectric layer; and a structural layer. The MEMS imaging actuator may be configured to effectuate one or more of OIS functionality and autofocus functionality. A feedback loop may be configured to process feedback signals that are indicative of a change in dielectric constant of a piezoelectric layer within the one or more multi-morphic thin film actuator assemblies.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a perspective view of a MEMS package in accordance with various embodiments of the present disclosure;

FIG. 2A is a diagrammatic view of an in-plane MEMS actuator with the optoelectronic device in accordance with various embodiments of the present disclosure;

FIG. 2B is a perspective view of an in-plane MEMS actuator with the optoelectronic device in accordance with various embodiments of the present disclosure;

FIG. 3 is a diagrammatic view of an in-plane MEMS actuator in accordance with various embodiments of the present disclosure;

FIG. 4 is a diagrammatic view of a comb drive sector in accordance with various embodiments of the present disclosure;

FIG. 5 is a diagrammatic view of a comb pair in accordance with various embodiments of the present disclosure;

FIG. 6 is a diagrammatic view of fingers of the comb pair of FIG. 5 in accordance with various embodiments of the present disclosure;

FIGS. 7A-7C are diagrammatic views of a piezoelectric out-of-plane actuator in accordance with various embodiments of the present disclosure;

FIG. 7D is a diagrammatic view of a piezoelectric in-plane actuator in accordance with various embodiments of the present disclosure;

FIG. 8 is a diagrammatic view of a MEMS package in accordance with various embodiments of the present disclosure;

FIGS. 9-11 are diagrammatic views of a MEMS imaging actuator assembly in accordance with various embodiments of the present disclosure;

FIG. 12 is a detail view of a motion control assembly in accordance with various embodiments of the present disclosure;

FIG. 13 is a detail view of an embedded snubber assembly in accordance with various embodiments of the present disclosure;

FIGS. 14-15 are diagrammatic views of a MEMS imaging actuator positioned within an optical path in accordance with various embodiments of the present disclosure; and

FIG. 16 is a detail view of an alternative embodiment of the motion control assembly of FIG. 12 in accordance with various embodiments of the present disclosure; Like reference symbols in the various drawings indicate like elements.

### DETAILED DESCRIPTION OF THE PREFERRED EMBODIMENTS

### System Overview:

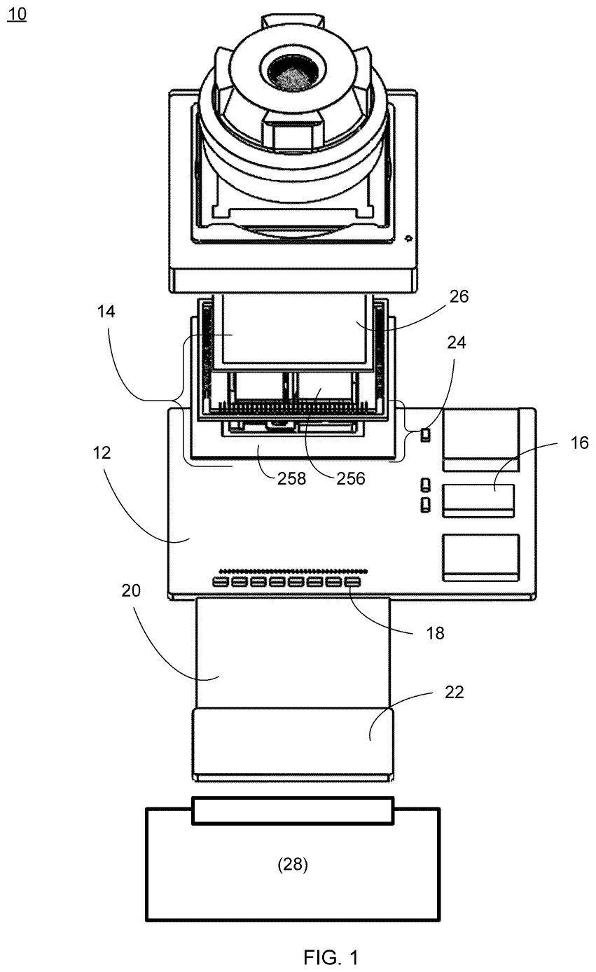

Referring to FIG. 1, there is shown MEMS package 10, in accordance with various aspects of this disclosure. In this example, MEMS package 10 is shown to include printed circuit board 12, multi-axis MEMS assembly 14, driver circuits 16, electronic components 18, flexible circuit 20, and electrical connector 22. Multi-axis MEMS assembly 14 may include micro-electrical-mechanical system (MEMS) actuator 24 (configured to provide linear three-axis movement and rotations about the same) and optoelectronic device 26 coupled to micro-electrical-mechanical system (MEMS) actuator 24.

As will be discussed below in greater detail, examples of micro-electrical-mechanical system (MEMS) actuator 24 may include but are not limited to an in-plane MEMS actuator, an out-of-plane MEMS actuator, and a combination in-plane/out-of-plane MEMS actuator. For example and if micro-electrical-mechanical system (MEMS) actuator 24 is an in-plane MEMS actuator, the in-plane MEMS actuator may include an electrostatic comb drive actuation system (as will be discussed below in greater detail). Additionally, if micro-electrical-mechanical system (MEMS) actuator 24 is an out-of-plane MEMS actuator, the out-of-plane MEMS actuator may include a piezoelectric actuation system or electrostatic actuation. And if micro-electrical-mechanical system (MEMS) actuator 24 is a hybrid in-plane/out-of-plane MEMS actuator, the combination in-plane/out-of-plane MEMS actuator may include an electrostatic comb drive actuation system and a piezoelectric actuation system.

As will be discussed below in greater detail, examples of optoelectronic device 26 may include but are not limited to an image sensor, a mirror, a single lens, a holder assembly, an IR filter and/or a lens assembly. Examples of electronic components 18 may include but are not limited to various electronic or semiconductor components and devices. Flexible circuit 20 and/or connector 22 may be configured to electrically couple MEMS package 10 to e.g., a smart phone or a digital camera (represented as generic item 28).

In some embodiments, some of the components of MEMS package 10 may be joined together using various epoxies/adhesives. For example, an outer frame of micro-electrical-mechanical system (MEMS) actuator 24 may include contact pads that may correspond to similar contact pads on printed circuit board 12.

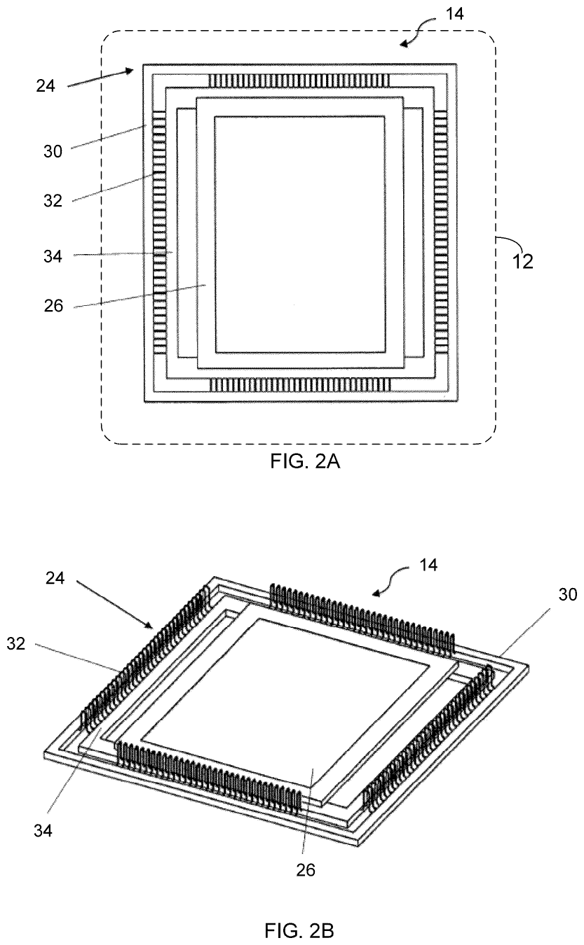

Referring also to FIG. 2A, there is shown multi-axis MEMS assembly 14, which may include optoelectronic device 26 coupled to micro-electrical-mechanical system (MEMS) actuator 24. As discussed above, examples of micro-electrical-mechanical system (MEMS) actuator 24 may include but are not limited to an in-plane MEMS actuator, an out-of-plane MEMS actuator, and a combination in-plane/out-of-plane MEMS actuator.

When configured to provide in-plane actuation functionality, micro-electrical-mechanical system (MEMS) actuator 24 may include outer frame 30, plurality of electrically conductive flexures 32, MEMS actuation core 34 for attaching a payload (e.g., a device), and attached optoelectronic device 26. Optoelectronic device 26 may be coupled to MEMS actuation core 34 of micro-electrical-mechanical system (MEMS) actuator 24 by epoxy (or various other adhesives/materials and/or bonding methods).

Referring also to FIG. 2B, plurality of electrically conductive flexures 32 of micro-electrical-mechanical system (MEMS) actuator 24 may be curved upward and buckled to achieve the desired level of flexibility & compression. In the illustrated embodiment, plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24).

Plurality of electrically conductive flexures 32 may be conductive wires that may extend above the plane (e.g., an upper surface) of micro-electrical-mechanical system (MEMS) actuator 24 and may electrically couple laterally separated components of micro-electrical-mechanical system (MEMS) actuator 24. For example, plurality of electrically conductive flexures 32 may provide electrical signals from optoelectronic device 26 and/or MEMS actuation core 34 to outer frame 30 of micro-electrical-mechanical system (MEMS) actuator 24. As discussed above, outer frame 30 of micro-electrical-mechanical system (MEMS) actuator 24 may be affixed to circuit board 12 using epoxy (or various other adhesive materials or devices).

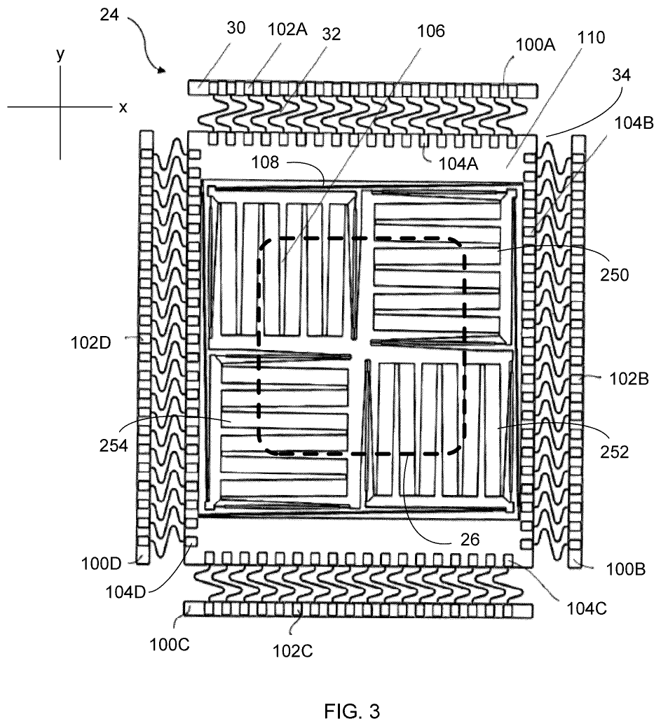

Referring also to FIG. 3, there is shown a top view of micro-electrical-mechanical system (MEMS) actuator 24 in accordance with various embodiments of the disclosure. Outer frame 30 is shown to include (in this example) four frame assemblies (e.g., frame assembly 100A, frame assembly 100B, frame assembly 100C, frame assembly 100D) that are shown as being spaced apart to allow for additional detail.

Outer frame 30 of micro-electrical-mechanical system (MEMS) actuator 24 may include a plurality of contact pads (e.g., contact pads 102A on frame assembly 100A, contact pads 102B on frame assembly 100B, contact pads 102C on frame assembly 100C, and contact pads 102D on frame assembly 100D), which may be electrically coupled to one end of plurality of electrically conductive flexures 32. The curved shape of electrically conductive flexures 32 is provided for illustrative purposes only and, while illustrating one possible embodiment, other configurations are possible and are considered to be within the scope of this disclosure.

MEMS actuation core 34 may include a plurality of contact pads (e.g., contact pads 104A, contact pads 104B, contact pads 104C, contact pads 104D), which may be electrically coupled to the other end of plurality of electrically conductive flexures 32. A portion of the contact pads (e.g., contact pads 104A, contact pads 104B, contact pads 104C, contact pads 104D) of MEMS actuation core 34 may be electrically coupled to optoelectronic device 26 by wire bonding, silver paste, or eutectic seal, thus allowing for the electrical coupling of optoelectronic device 26 to outer frame 30.

### Electrostatic Actuation

MEMS actuation core 34 may include one or more comb drive sectors (e.g., comb drive sector 106) that are actuation sectors disposed within micro-electrical-mechanical system (MEMS) actuator 24. The comb drive sectors (e.g., comb drive sector 106) within MEMS actuation core 34 may be disposed in the same plane and may be positioned orthogonal to each other to allow for movement in two axes (e.g., the X-axis and the Y-axis). Accordingly, the in-plane MEMS actuator generally (and MEMS actuation core 34 specifically) may be configured to provide linear X-axis movement and linear Y-axis movement and rotation about the Z-axis.

While in this particular example, MEMS actuation core 34 is shown to include four comb drive sectors, this is for illustrative purposes only and is not intended to be a limitation of this disclosure, as other configurations are possible. For example, the number of comb drive sectors may be increased or decreased depending upon design criteria.

While in this particular example, the four comb drive sectors are shown to be generally square in shape, this is for illustrative purposes only and is not intended to be a limitation of this disclosure, as other configurations are possible. For example, the shape of the comb drive sectors may be changed to meet various design criteria.

While the comb drive sectors (e.g., comb drive sector 106) within MEMS actuation core 34 are shown to be positioned orthogonal to each other to allow for movement in two axes (e.g., the X-axis and the Y-axis), this is for illustrative purposes only and is not intended to be a limitation of this disclosure, as other configurations are possible. For example, the comb drive sectors (e.g., comb drive sector 106) within MEMS actuation core 34 may be positioned parallel to each other to allow for movement in a single axis (e.g., either the X-axis or the Y-axis).

Each comb drive sector (e.g., comb drive sector 106) within MEMS actuation core 34 may include one or more moving portions and one or more fixed portions. As will be discussed below in greater detail, a comb drive sector (e.g., comb drive sector 106) within MEMS actuation core 34 may be coupled, via a cantilever assembly (e.g., cantilever assembly 108), to outer periphery 110 of MEMS actuation core 34 (i.e., the portion of MEMS actuation core 34 that includes contact pads 104A, contact pads 104B, contact pads 104C, contact pads 104D), which is the portion of MEMS actuation core 34 to which optoelectronic device 26 may be coupled, thus effectuating the transfer of movement to optoelectronic device 26.

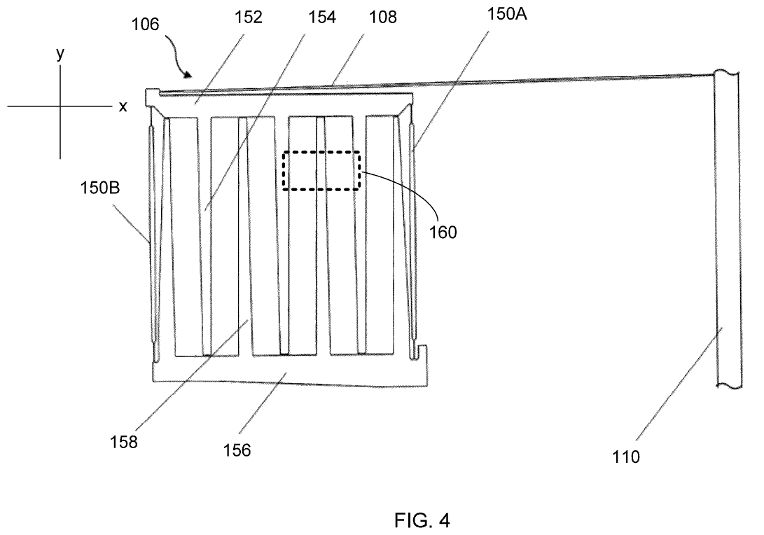

Referring also to FIG. 4, there is shown a top view of comb drive sector 106 in accordance with various embodiments of the present disclosure. Each comb drive sector (e.g., comb drive sector 106) may include one or more motion control cantilever assemblies (e.g., motion control cantilever assemblies 150A, 150B) positioned outside of comb drive sector 106, moveable frame 152, moveable spines 154, fixed frame 156, fixed spines 158, and cantilever assembly 108 that is configured to couple moving frame 152 to outer periphery 110 of MEMS actuation core 34. In this particular configuration, motion control cantilever assemblies 150A, 150B may be configured to prevent Y-axis displacement between moving frame 152/moveable spines 154 and fixed frame 156/fixed spines 158.

Comb drive sector 106 may include a movable member including moveable frame 152 and multiple moveable spines 154 that are generally orthogonal to moveable frame 152. Comb drive sector 106 may also include a fixed member including fixed frame 156 and multiple fixed spines 158 that are generally orthogonal to fixed frame 156. Cantilever assembly 108 may be deformable in one direction (e.g., in response to Y-axis deflective loads) and rigid in another direction (e.g., in response to X-axis tension and compression loads), thus allowing for cantilever assembly 108 to absorb motion in the Y-axis but transfer motion in the X-axis.

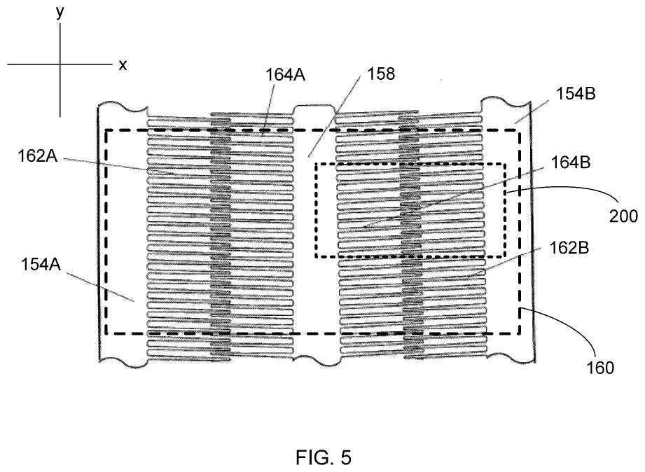

Referring also to FIG. 5, there is shown a detail view of portion 160 of comb drive sector 106. Moveable spines 154A, 154B may include a plurality of discrete moveable actuation fingers that are generally orthogonally-attached to moveable spines 154A, 154B. For example, moveable spine 154A is shown to include moveable actuation fingers 162A and moveable spine 154B is shown to include moveable actuation fingers 162B.

Further, fixed spine 158 may include a plurality of discrete fixed actuation fingers that are generally orthogonally-attached to fixed spine 158. For example, fixed spine 158 is shown to include fixed actuation fingers 164A that are configured to mesh and interact with moveable actuation fingers 162A. Further, fixed spine 158 is shown to include fixed actuation fingers 164B that are configured to mesh and interact with moveable actuation fingers 162B.

Accordingly, various numbers of actuation fingers may be associated with (i.e., coupled to) the moveable spines (e.g., moveable spines 154A, 154B) and/or the fixed spines (e.g., fixed spine 158) of comb drive sector 106. As discussed above, each comb drive sector (e.g., comb drive sector 106) may include two motion control cantilever assemblies 150A, 150B separately placed on each side of comb drive sector 106. Each of the two motion control cantilever assemblies 150A, 150B may be configured to couple moveable frame 152 and fixed frame 156, as this configuration enables moveable actuation fingers 162A, 162B to be displaceable in the X-axis with respect to fixed actuation fingers 164A, 164B (respectively) while preventing moveable actuation fingers 162A, 162B from being displaced in the Y-axis and contacting fixed actuation fingers 164A, 164B (respectively).

While actuation fingers 162A, 162B, 164A, 164B (or at least the center axes of actuation fingers 162A, 162B, 164A, 164B) are shown to be generally parallel to one another and generally orthogonal to the respective spines to which they are coupled, this is for illustrative purposes only and is not intended to be a limitation of this disclosure, as other configurations are possible. Further and in some embodiments, actuation fingers 162A, 162B, 164A, 164B may have the same width throughout their length and in other embodiments, actuation fingers 162A, 162B, 164A, 164B may be tapered.

Further and in some embodiments, moveable frame 152 may be displaced in the positive X-axis direction when a voltage potential is applied between actuation fingers 162A and actuation fingers 164A, while moveable frame 152 may be displaced in the negative X-axis direction when a voltage potential is applied between actuation fingers 162B and actuation fingers 164B.

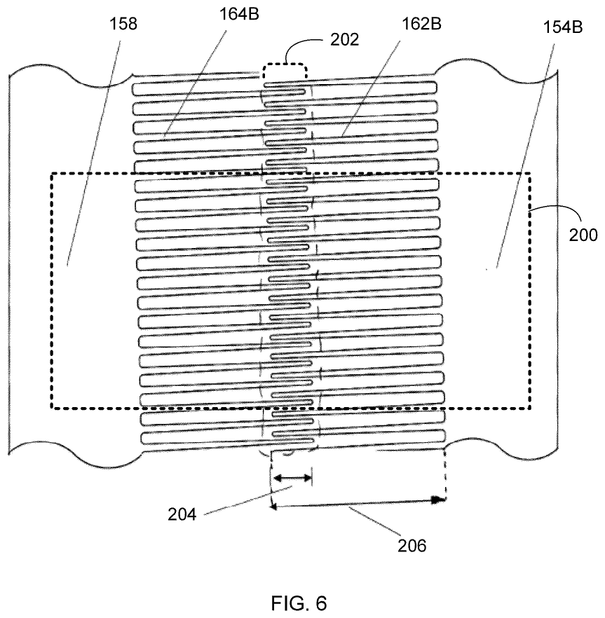

Referring also to FIG. 6, there is shown a detail view of portion 200 of comb drive sector 106. Fixed spine 158 may be generally parallel to moveable spine 154B, wherein actuation fingers 164B and actuation fingers 162B may overlap within region 202, wherein the width of overlap region 202 is typically in the range of 10-50 microns. While overlap region 202 is described as being in the range of 10-50 microns, this is for illustrative purposes only and is not intended to be a limitation of this disclosure, as other configurations are possible.

Overlap region 202 may represent the distance 204 where the ends of actuation fingers 162B extends past and overlap the ends of actuation fingers 164B, which are interposed therebetween. In some embodiments, actuation fingers 162B and actuation fingers 164B may be tapered such that their respective tips are narrower than their respective bases (i.e., where they are attached to their spines). As is known in the art, various degrees of taper may be utilized with respect to actuation fingers 162B and actuation fingers 164B. Additionally, the overlap of actuation fingers 162B and actuation fingers 164B provided by overlap region 202 may help ensure that there is sufficient initial actuation force when an electrical voltage potential is applied so that MEMS actuation core 34 may move gradually and smoothly without any sudden jumps when varying the applied voltage. The height of actuation fingers 162B and actuation fingers 164B may be determined by various aspects of the MEMS fabrication process and various design criteria.

Length 206 of actuation fingers 162B and actuation fingers 164B, the size of overlap region 202, the gaps between adjacent actuation fingers, and actuation finger taper angles that are incorporated into various embodiments may be determined by various design criteria, application considerations, and manufacturability considerations, wherein these measurements may be optimized to achieve the required displacement utilizing the available voltage potential.

As shown in FIG. 3 and as discussed above, MEMS actuation core 34 may include one or more comb drive sectors (e.g., comb drive sector 106), wherein the comb drive sectors (e.g., comb drive sector 106) within MEMS actuation core 34 may be disposed in the same plane and may be positioned orthogonal to each other to allow for movement in two axes (e.g., the X-axis and the Y-axis).

Specifically and in this particular example, MEMS actuation core 34 is shown to include four comb drive sectors (e.g., comb drive sectors 106, 250, 252, 254). As discussed above, comb drive sector 106 is configured to allow for movement along the X-axis, while preventing movement along the Y-axis. As comb drive sector 252 is similarly configured, comb drive sector 252 may allow for movement along the X-axis, while preventing movement along the Y-axis. Accordingly, if a signal is applied to comb drive sector 106 that provides for positive X-axis movement, while a signal is applied to comb drive sector 252 that provides for negative X-axis movement, actuation core 34 may be displaced in a clockwise direction. Conversely, if a signal is applied to comb drive sector 106 that provides for negative X-axis movement, while a signal is applied to comb drive sector 252 that provides for positive X-axis movement, actuation core 34 may be displaced in a counterclockwise direction.

Further, comb drive sectors 250, 254 are configured (in this example) to be orthogonal to comb drive sectors 106, 252. Accordingly, comb drive sectors 250, 254 may be configured to allow for movement along the Y-axis, while preventing movement along the X-axis. Accordingly, if a signal is applied to comb drive sector 250 that provides for positive Y-axis movement, while a signal is applied to comb drive sector 254 that provides for negative Y-axis movement, actuation core 34 may be displaced in a counterclockwise direction. Conversely, if a signal is applied to comb drive sector 250 that provides for negative Y-axis movement, while a signal is applied to comb drive sector 254 that provides for positive Y-axis movement, actuation core 34 may be displaced in a clockwise direction.

Accordingly, the in-plane MEMS actuator generally (and MEMS actuation core 34 specifically) may be configured to provide rotational (e.g., clockwise or counterclockwise) Z-axis movement

### Piezoelectric Actuation

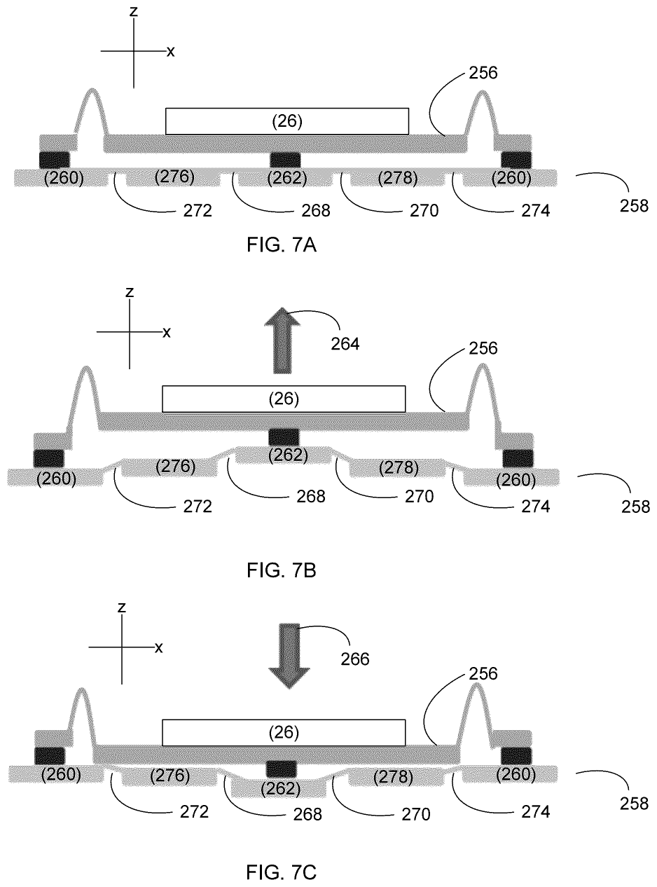

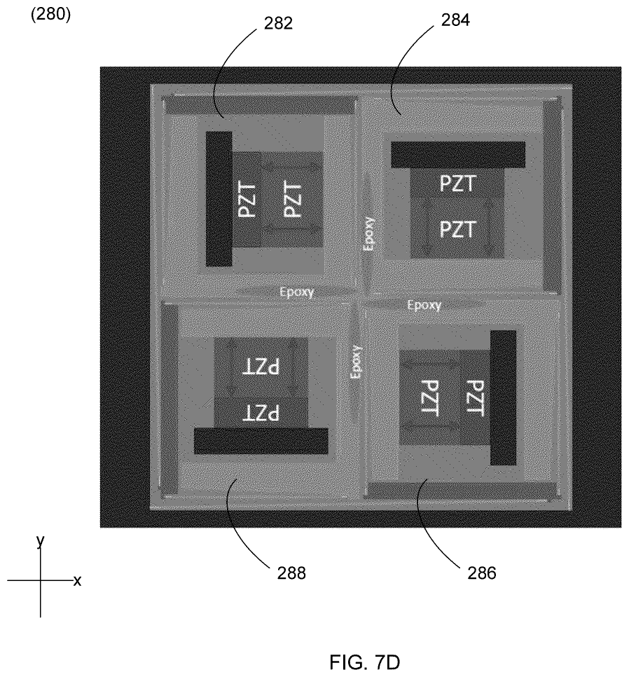

As stated above, examples of micro-electrical-mechanical system (MEMS) actuator 24 may include but are not limited to an in-plane MEMS actuator, an out-of-plane MEMS actuator, and a combination in-plane/out-of-plane MEMS actuator. For example and referring also to FIGS. 7A-7C, micro-electrical-mechanical system (MEMS) actuator 24 is shown to include an in-plane MEMS actuator (e.g., in-plane MEMS actuator 256) and an out-of-plane MEMS actuator (e.g., out-of-plane MEMS actuator 258), wherein FIGS. 3-6 illustrate one possible embodiment of in-plane MEMS actuator 256. Optoelectronic device 26 may be coupled to in-plane MEMS actuator 256; and in-plane MEMS actuator 256 may be coupled to out-of-plane MEMS actuator 258.

An example of in-plane MEMS actuator 256 may include but is not limited to an image stabilization actuator. As is known in the art, image stabilization is a family of techniques that reduce blurring associated with the motion of a camera or other imaging device during exposure. Generally, it compensates for pan and tilt (angular movement, equivalent to yaw and pitch) of the imaging device, though electronic image stabilization may also compensate for rotation. Image stabilization may be used in image-stabilized binoculars, still and video cameras, astronomical telescopes, and smartphones. With still cameras, camera shake may be a particular problem at slow shutter speeds or with long focal length (telephoto or zoom) lenses. With video cameras, camera shake may cause visible frame-to-frame jitter in the recorded video. In astronomy, the problem may be amplified by variations in the atmosphere (which changes the apparent positions of objects over time).

An example of out-of-plane MEMS actuator 258 may include but is not limited to an autofocus actuator. As is known in the art, an autofocus system may use a sensor, a control system and an actuator to focus on an automatically (or manually) selected area. Autofocus methodologies may be distinguished by their type (e.g., active, passive or hybrid). Autofocus systems may rely on one or more sensors to determine correct focus, wherein some autofocus systems may rely on a single sensor while others may use an array of sensors.

FIGS. 7A-7C show one possible embodiment of out-of-plane MEMS actuator 258 in various states of activation/excitation. Out-of-plane MEMS actuator 258 may include frame 260 (which is configured to be stationary) and moveable stage 262, wherein out-of-plane MEMS actuator 258 may be configured to provide linear Z-axis movement. For example, out-of-plane MEMS actuator 258 may include a multi-morph piezoelectric actuator that may be selectively and controllably deformable when an electrical charge is applied, wherein the polarity of the applied electrical charge may vary the direction in which the multi-morph piezoelectric actuator (i.e., out-of-plane MEMS actuator 258) is deformed. For example, FIG. 7A shows out-of-plane MEMS actuator 258 in a natural position without an electrical charge being applied. Further, FIG. 7B shows out-of-plane MEMS actuator 258 in an extended position (i.e., displaced in the direction of arrow 264) with an electrical charge having a first polarity being applied, while FIG. 7C shows out-of-plane MEMS actuator 258 in a retracted position (i.e., displaced in the direction of arrow 266) with an electrical charge having an opposite polarity being applied.

As discussed above, the multi-morph piezoelectric actuator (i.e., out-of-plane MEMS actuator 258) may be deformable by applying an electrical field. In order to accomplish such deformability that allows for such linear Z-axis movement, the multi-morph piezoelectric actuator (i.e., out-of-plane MEMS actuator 258) may include a bending piezoelectric actuator.

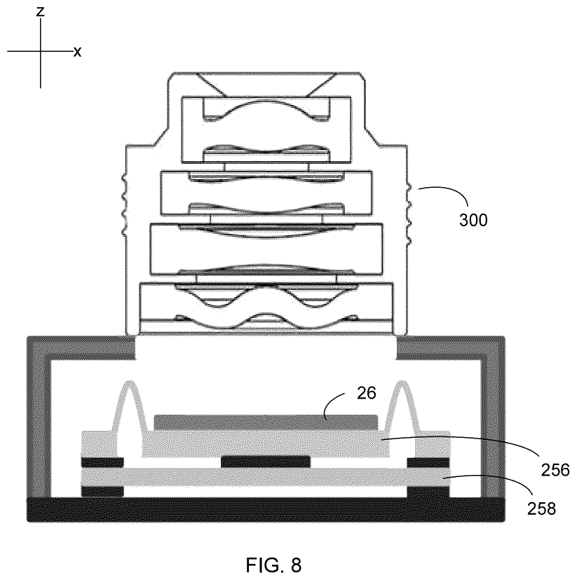

As discussed above, the multi-morph piezoelectric actuator (i.e., out-of-plane MEMS actuator 258) may include rigid frame assembly 260 (which is configured to be stationary) and moveable stage 262 that may be configured to be affixed to in-plane MEMS actuator 256. As discussed above, optoelectronic device 26 may be coupled to in-plane MEMS actuator 256 and in-plane MEMS actuator 256 may be coupled to out-of-plane MEMS actuator 258. Accordingly and when out-of-plane MEMS actuator 258 is in an extended position (i.e., displaced in the direction of arrow 264) with an electrical field having a first polarity being applied (as shown in FIG. 7B), optoelectronic device 26 may be displaced in the positive z-axis direction and towards a lens assembly (e.g., lens assembly 300, FIG. 8). Alternatively and when out-of-plane MEMS actuator 258 is in a retracted position (i.e., displaced in the direction of arrow 266) with an electrical field having an opposite polarity being applied (as shown in FIG. 7C), optoelectronic device 26 may be displaced in the negative z-axis direction and away from a lens assembly (e.g., lens assembly 300, FIG. 8). Accordingly and by displacing optoelectronic device 26 in the z-axis with respect to a lens assembly (e.g., lens assembly 300, FIG. 8), autofocus functionality may be achieved.

The multi-morph piezoelectric actuator (i.e., out-of-plane MEMS actuator 258) may include at least one deformable piezoelectric portion (e.g., deformable piezoelectric portions 268, 270, 272, 274) configured to couple moveable stage 262 to rigid frame assembly 260.

For example and in one particular embodiment, multi-morph piezoelectric actuator (i.e., out-of-plane MEMS actuator 258) may include a rigid intermediate stage (e.g., rigid intermediate stages 276, 278). A first deformable piezoelectric portion (e.g., deformable piezoelectric portions 268, 270) may be configured to couple rigid intermediate stage (e.g., rigid intermediate stages 276, 278) to moveable stage 262; and a second deformable piezoelectric portion (e.g., deformable piezoelectric portions 272, 274) may be configured to couple the rigid intermediate stage (e.g., rigid intermediate stages 276, 278) to rigid frame assembly 260.

Linear Z-axis (i.e., out-of-plane) movement of moveable stage 262 of out-of-plane MEMS actuator 258 may be generated due to the deformation of the deformable piezoelectric portion (e.g., deformable piezoelectric portions 268, 270, 272, 274), which may be formed of a piezoelectric material (e.g., PZT (lead zirconate titanate), zinc oxide or other suitable material) that may be configured to deflect in response to an electrical signal. As is known in the art, piezoelectric materials are a special type of ceramic that expands or contracts when an electrical field is applied, thus generating motion and force.

While out-of-plane MEMS actuator 258 is described above as including a single moveable stage (e.g., moveable stage 262) that enables linear movement in the Z-axis, this is for illustrative purposes only and is not intended to be a limitation of this disclosure, as other configurations are possible and are considered to be within the scope of this disclosure. For example, out-of-plane MEMS actuator 258 may be configured to include multiple moveable stages. For example, if deformable piezoelectric portions 272, 274 were configured to be separately controllable, additional degrees of freedom (such as tip and/or tilt) may be achievable. For example and in such a configuration, displacing intermediate stage 276 in an upward direction (i.e., in the direction of arrow 264) while displacing intermediate stage 278 in a downward direction (i.e., in the direction of arrow 266) would result in clockwise rotation of optoelectronic device 26 about the Y-axis; while displacing intermediate stage 276 in a downward direction (i.e., in the direction of arrow 266) while displacing intermediate stage 278 in a upward direction (i.e., in the direction of arrow 264) would result in counterclockwise rotation of optoelectronic device 26 about the Y-axis. Additionally/alternatively, corresponding clockwise and counterclockwise rotation of optoelectronic device 26 about the X-axis may be achieved via additional/alternative intermediate stages.

While FIGS. 7A-7C each show one possible embodiment of an out-of-plane piezoelectric MEMS actuator in various states of activation/excitation, this is for illustrative purposes only and is not intended to be a limitation of this disclosure, as other configurations are possible and are considered to be within the scope of this disclosure. For example and as shown in FIG. 7D, in-plane piezoelectric MEMS actuator 280 may be formed in a fashion similar to that of the above-described in-plane electrostatic MEMS actuators. Accordingly, in-plane piezoelectric MEMS actuator 280 may include a plurality of piezoelectric drive sectors (e.g., piezoelectric drive sectors 282, 284, 286, 288) configured in a similar orthogonal fashion (e.g., piezoelectric drive sectors 282, 286 being configured to enable movement in one axis and piezoelectric drive sectors 284, 288 being configured to enable movement in an orthogonal axis), thus enabling movement in the X-axis and the Y-axis, and rotation about the Z-axis.

### MEMS Actuator Assembly:

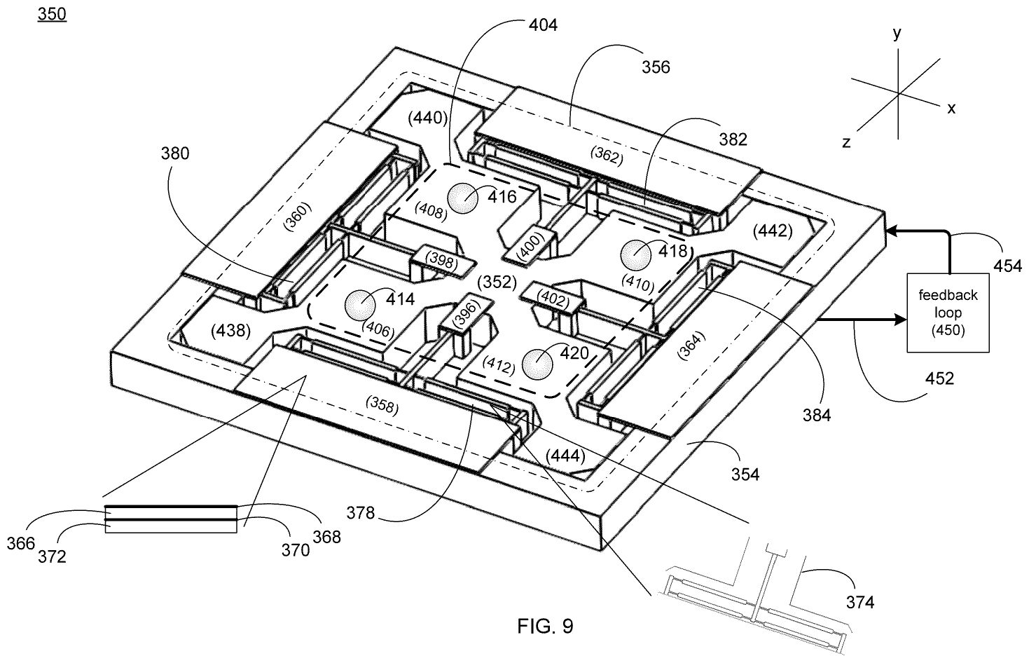

Referring also to FIG. 9, there is shown a MEMS imaging actuator assembly (e.g., MEMS imaging actuator assembly 350). The MEMS imaging actuator assembly (e.g., MEMS imaging actuator assembly 350) may include a first structural assembly (e.g., first structural assembly 352) and/or a second structural assembly (e.g., second structural assembly 354).

The first structural assembly (e.g., first structural assembly 352) and/or a second structural assembly (e.g., second structural assembly 354) may be constructed of a MEMS material, examples of which may include but are not limited to:
Silicon (Si): Silicon is a widely used material in MEMS fabrication due to its excellent mechanical and electrical properties. Silicon wafers serve as the substrate for many MEMS devices. The compatibility of silicon with microfabrication processes, such as photolithography and etching, makes it a popular choice.
Polymers: Various polymers, such as polyimide and SU-8, are used in MEMS for their flexibility and lightweight properties. Polymers are suitable for certain applications where flexibility or biocompatibility is essential.
Metals: Metals like aluminum, gold, and copper are used in MEMS for electrical interconnections and as structural elements. They provide good electrical conductivity and can be deposited and patterned using microfabrication techniques.
Ceramics: Certain ceramics, including silicon carbide (SiC) and aluminum nitride (AlN), are used in MEMS for their mechanical and thermal properties. They find applications in sensors and actuators that require high-temperature stability and resistance.
Glass: Glass materials, like borosilicate glass, can be used for MEMS applications, especially in cases where transparency or specific optical properties are required.
Silicon Dioxide (SiO₂) and Silicon Nitride (Si3N4): These materials are commonly used as insulating layers in MEMS devices. They provide electrical isolation between different layers and components.
Composites: Some MEMS devices may use composite materials to achieve a combination of specific properties. For example, combining polymers with nanoparticles can result in materials with enhanced mechanical or thermal characteristics.

The MEMS imaging actuator assembly (e.g., MEMS imaging actuator assembly 350) may include a tip-tilt displacement assembly (e.g., tip-tilt displacement assembly 356), configured to position the first structural assembly (e.g., first structural assembly 352) with respect to the second structural assembly (e.g., second structural assembly 354).

The tip-tilt displacement assembly (e.g., tip-tilt displacement assembly 356) may include one or more multi-morphic thin film actuator assemblies (e.g., one or more multi-morphic thin film actuator assemblies 358, 360, 362, 364).

Further, the one or more multi-morphic thin film actuator assemblies (e.g., one or more multi-morphic thin film actuator assemblies 358, 360, 362, 364} may include: a piezoelectric layer (e.g., piezoelectric layer 366), one or more electrodes (e.g., one or more electrodes 368, 370) positioned proximate the piezoelectric layer (e.g., piezoelectric layer 366) and/or one or more structural layers (e.g., structural layer 372).

As is known in the art, piezoelectric materials (e.g., piezoelectric layer 366) are materials that generate an electric charge in response to mechanical stress and, conversely, undergo mechanical deformation when an electric field is applied. The term “piezoelectric” is derived from the Greek word “piezein,” which means to squeeze or press.

Generally speaking, piezoelectric materials (e.g., piezoelectric layer 366) operate as follows:
Crystalline Structure: Piezoelectricity is typically observed in certain crystals, ceramics, and polymers that possess a non-centrosymmetric crystal structure. A non-centrosymmetric structure means that the positive and negative charges within the unit cell are not symmetrically arranged.
Direct Piezoelectric Effect: When mechanical stress or pressure is applied to a piezoelectric material, the crystal lattice deforms, causing a displacement of positive and negative charges within the crystal structure. This displacement results in the generation of an electric field across the material, creating a voltage potential. This phenomenon is known as the direct piezoelectric effect.
Converse Piezoelectric Effect: Conversely, when an electric field is applied (e.g., via electrodes 368, 370) to the piezoelectric material (e.g., piezoelectric layer 366), the electric field causes the crystal lattice to deform, leading to mechanical displacement. This is called the converse piezoelectric effect.
Applications: Piezoelectric materials find applications in various devices and technologies. Common examples include but are not limited to:
   Ultrasound Transducers: Piezoelectric crystals are used in medical ultrasound transducers to generate and receive ultrasonic waves.
   Piezoelectric Sensors: Piezoelectric sensors are used in various applications, such as pressure sensors, accelerometers, and strain gauges.
   Piezoelectric Actuators: Piezoelectric actuators are used for precise positioning in devices like inkjet printers and autofocus mechanisms in cameras.
   Energy Harvesting: Piezoelectric materials can convert mechanical vibrations and movements into electrical energy, making them suitable for energy harvesting in certain applications.
Materials: Common piezoelectric materials include quartz, lead zirconate titanate (PZT), and various other ceramics and crystals. The choice of material depends on the specific application requirements.

Accordingly and through the use of the tip-tilt displacement assembly (e.g., tip-tilt displacement assembly 356) generally and the one or more multi-morphic thin film actuator assemblies (e.g., one or more multi-morphic thin film actuator assemblies 358, 360, 362, 364) specifically, the position of the first structural assembly (e.g., first structural assembly 352) may be displaced with respect to the second structural assembly (e.g., second structural assembly 354).

For example (as shown in FIG. 9), the second structural assembly (e.g., second structural assembly 354) may be rigidly affixed and the first structural assembly (e.g., first structural assembly 352) may be configured to be displaceable by the tip-tilt displacement assembly (e.g., tip-tilt displacement assembly 356) with respect to the second structural assembly (e.g., second structural assembly 354). For example and depending upon the manner in which the MEMS imaging actuator assembly (e.g., MEMS imaging actuator assembly 350) is configured, one or more portions of the first structural assembly (e.g., first structural assembly 352) may be displaced upward (i.e., in the positive Y-axis) with respect to the second structural assembly (e.g., second structural assembly 354). Additionally/alternatively, one or more portions of the first structural assembly (e.g., first structural assembly 352) may be displaced downward (i.e., in the negative Y-axis) with respect to the second structural assembly (e.g., second structural assembly 354).

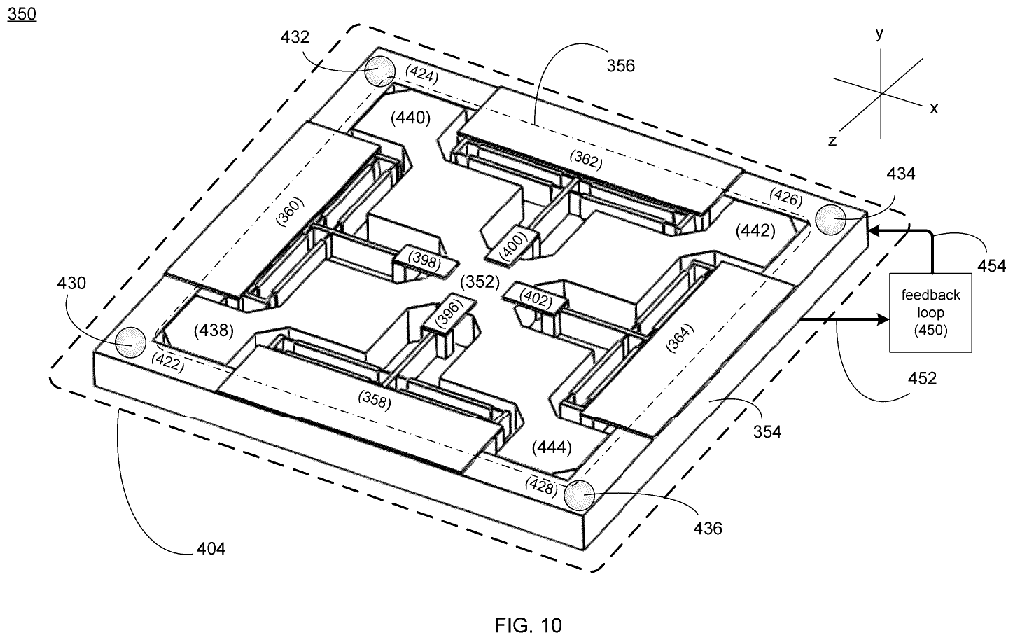

Alternatively and referring also to FIG. 10, the first structural assembly (e.g., first structural assembly 352) may be rigidly affixed and the second structural assembly (e.g., second structural assembly 354) may be configured to be displaceable by the tip-tilt displacement assembly (e.g., tip-tilt displacement assembly 356) with respect to the first structural assembly (e.g., first structural assembly 352). For example and depending upon the manner in which the MEMS imaging actuator assembly (e.g., MEMS imaging actuator assembly 350) is configured, one or more portions of the second structural assembly (e.g., second structural assembly 354) may be displaced upward (i.e., in the positive Y-axis) with respect to the first structural assembly (e.g., first structural assembly 352). Additionally/alternatively, one or more portions of the second structural assembly (e.g., second structural assembly 354) may be displaced downward (i.e., in the negative Y-axis) with respect to the first structural assembly (e.g., first structural assembly 352).

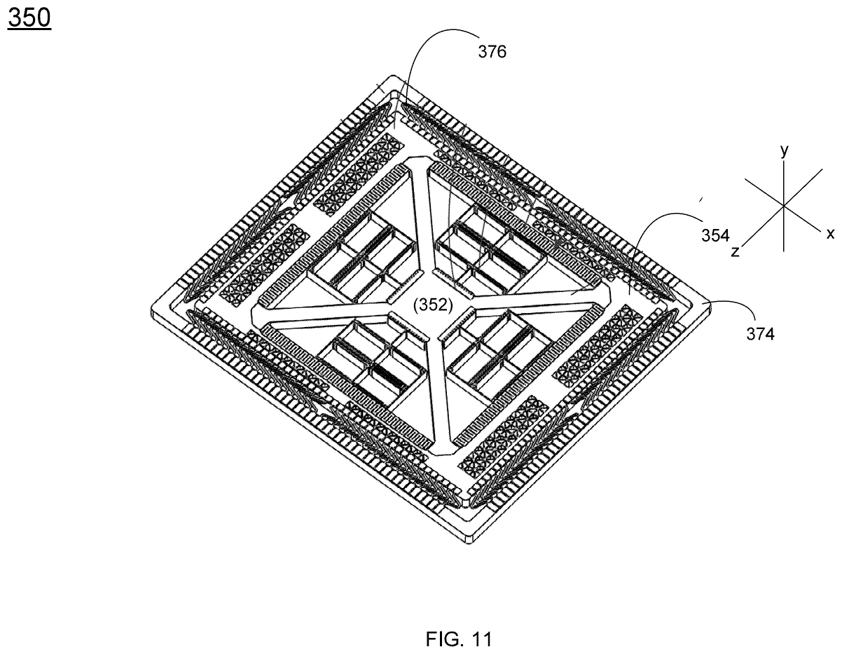

Accordingly and referring also to FIG. 11, when the first structural assembly (e.g., first structural assembly 352) is rigidly affixed and the second structural assembly (e.g., second structural assembly 354) is displaceable by the tip-tilt displacement assembly (e.g., tip-tilt displacement assembly 356) with respect to the first structural assembly (e.g., first structural assembly 352), MEMS imaging actuator assembly 350 may include an outer frame assembly (e.g., outer frame assembly 374) positioned proximate the second structural assembly (e.g., second structural assembly 354). Outer frame assembly 374 may be rigidly affixed and electrically coupled to second structural assembly 354. For example, the MEMS imaging actuator assembly (e.g., MEMS imaging actuator assembly 350) may include one or more electrically conductive flexures (e.g., one or more electrically conductive flexures 376) configured to electrically couple the outer frame assembly (e.g., outer frame assembly 374) and the second structural assembly (e.g., second structural assembly 354). As these electrically conductive flexures (e.g., one or more electrically conductive flexures 376) are flexible, they may allow continued electrical connection between outer frame assembly 374 (which is rigidly-affixed) and second structural assembly 354 (which is displaceable).

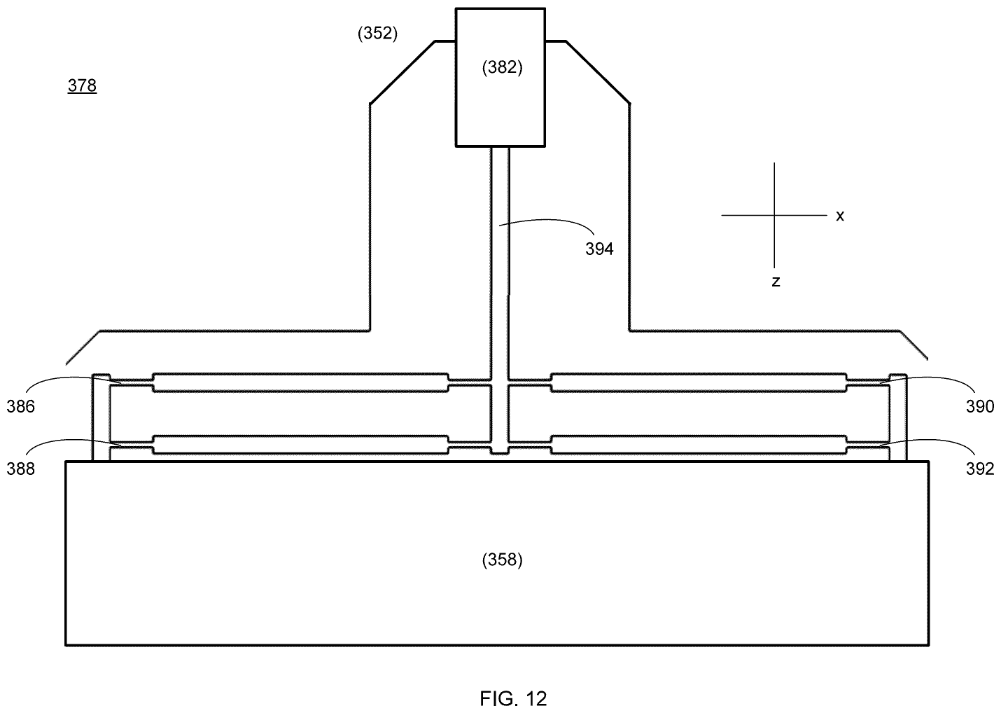

The tip-tilt displacement assembly (e.g., tip-tilt displacement assembly 356) may include one or more motion control assemblies (e.g., one or more motion control assemblies 378, 380, 382, 384). Referring also to FIG. 12, there is shown a detail view of a motion control assembly (e.g., motion control assembly 378, which includes multiple cantilevers, wherein the number of cantilevers are not limited to that shown in this figure. In this particular embodiment, motion control assembly 378 is shown to include four cantilever assemblies (e.g., cantilever assemblies 386, 388, 390, 392) that are configured to restrain movement of central arm 394 in the X-axis and also act as a motion amplifier.

The tip-tilt displacement assembly (e.g., tip-tilt displacement assembly 356) may include one or more multi-morphic/mono-morphic thin film assemblies (e.g., one or more multi-morphic/mono-morphic thin film assemblies 396, 398, 400, 402). These multi-morphic/mono-morphic thin film assemblies (e.g., multi-morphic/mono-morphic thin film assemblies 396, 398, 400, 402) may be active multi-morphic thin film assemblies, such as those that are actuated via piezoelectric materials and assist in the positioning of the first structural assembly (e.g., first structural assembly 352) with respect to the second structural assembly (e.g., second structural assembly 354). Alternatively, these multi-morphic/mono-morphic thin film assemblies (e.g., multi-morphic/mono-morphic thin film assemblies 396, 398, 400, 402) may be passive mono-morphic thin film assemblies, such as those that simply function as flexible joints.

One of the structural assemblies (e.g., structural assemblies 352, 354) may be configured to mount an optical device (e.g., optical device 404), examples of which may include but are not limited to a mirror assembly and an image sensor assembly.

In a camera system, a mirror assembly is a optical component having a primary role of directing light toward an image sensor.

In a camera system, an image sensor assembly captures light and converts it into an electronic signal for creating digital images. At the core of this assembly is the image sensor, which can be either CCD (Charge-Coupled Device) or CMOS (Complementary Metal-Oxide-Semiconductor). This sensor comprises an array of photosites, each representing a pixel in the final image. To capture color information, a Color Filter Array (CFA) is often used, typically in a Bayer pattern of red, green, and blue filters over individual photosites. Micro lenses are placed above each photosite to enhance light sensitivity.

One of the structural assemblies (e.g., structural assemblies 352, 354) may include: one or more glue pads for affixing the optical device (e.g., optical device 404). For example:
As shown in FIG. 9, first structural assembly 352 may include glue pads 406, 408, 410, 412 configured to receive portions of adhesive 414, 416, 418, 420 for affixing optical device 404 to first structural assembly 352.
As shown in FIG. 10, second structural assembly 354 may include glue pads 422, 424, 426, 428 configured to receive portions of adhesive 430, 432, 434, 436 for affixing optical device 404 to second structural assembly 354. The quantity of adhesive is not limited to that shown in the picture, as it could cover the four sides of the second structural assembly 354.

Accordingly, the tip-tilt displacement assembly (e.g., tip-tilt displacement assembly 356) may be configured to allow rotation of the optical device (e.g., optical device 404) is multiple axes (e.g., the X-axis and/or the Z-axis).

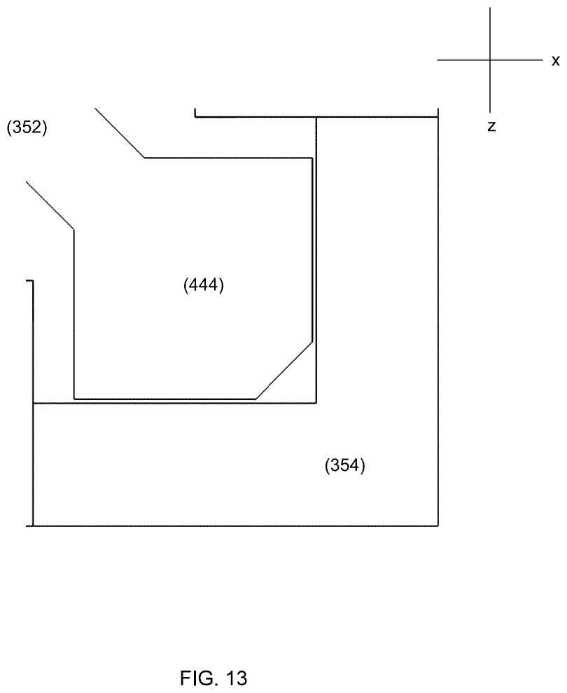

Referring also to FIG. 13, the first structural assembly (e.g., first structural assembly 352) may include: one or more embedded snubber assemblies (e.g., one or more embedded snubber assemblies 438, 440, 442, 444 shown in FIG. 9-10) configured to interface with the second structural assembly (e.g., second structural assembly 354) and limit in-plane movement (e.g., along the X-axis and Z-axis) of the first structural assembly (e.g., first structural assembly 352).

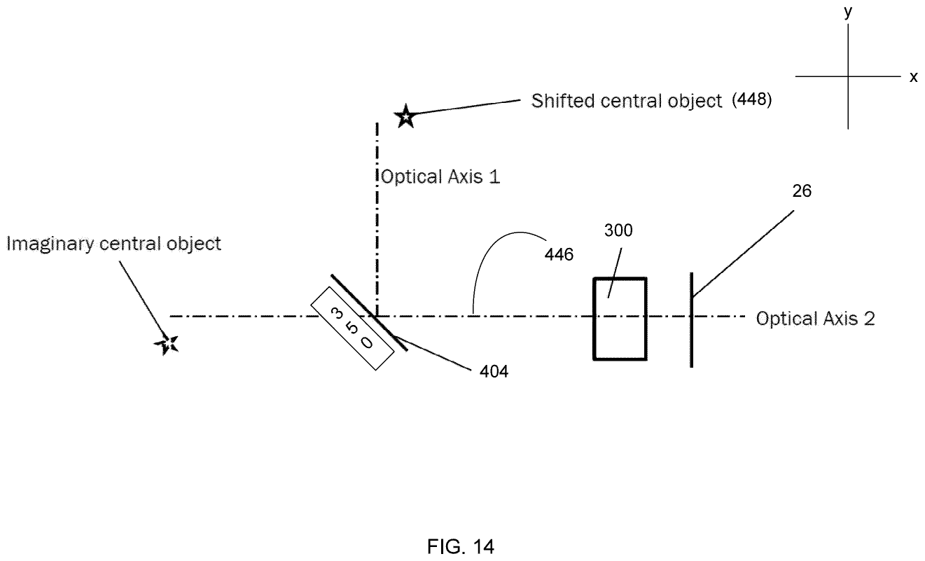

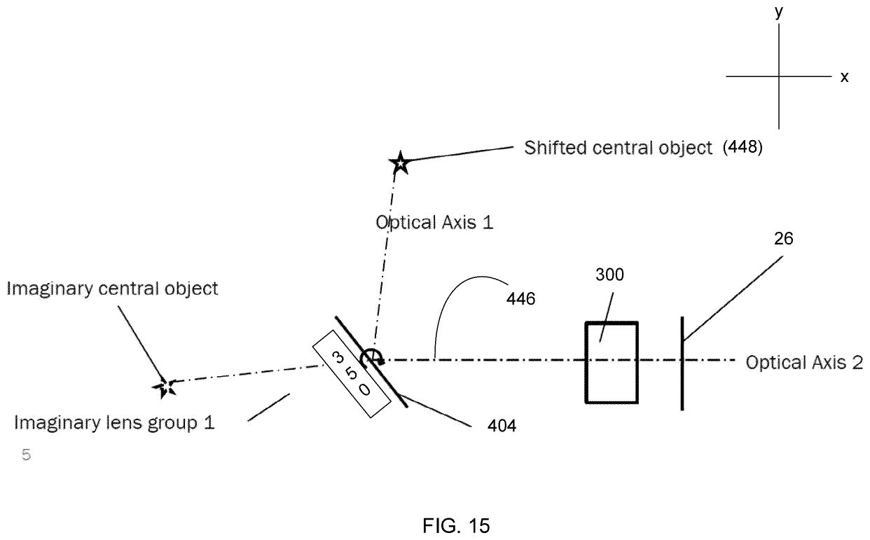

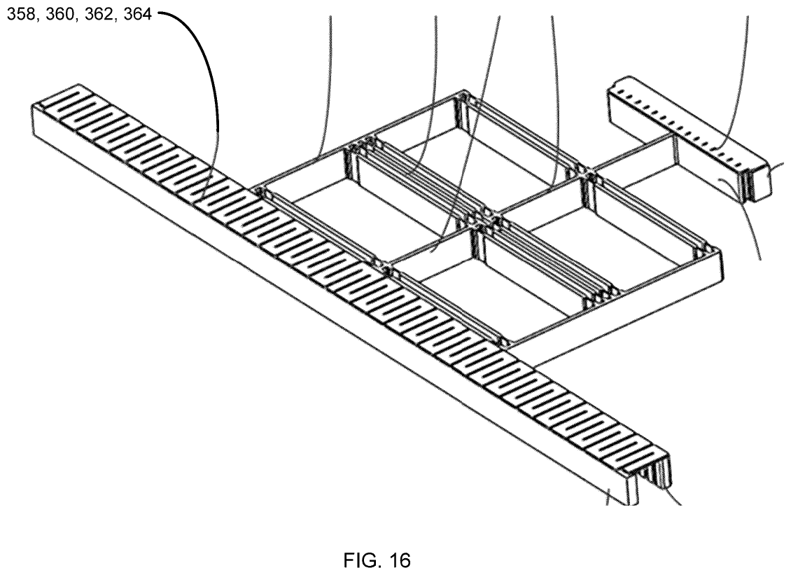

Referring also to FIGS. 14-15, the MEMS imaging actuator assembly (e.g., MEMS imaging actuator assembly 350) may be configured to effectuate one or more of OIS functionality and autofocus functionality. Optical image stabilization (OIS) is a technology designed to mitigate the impact of hand tremors and other forms of motion while capturing images or recording videos with cameras, particularly in smartphones and digital cameras. The primary goal of OIS is to produce clearer, sharper images by compensating for involuntary movements that can occur when holding a camera. This is achieved through the use of specialized mechanisms within the camera lens or image sensor that counteract the effects of motion in real-time. When the system detects movements, it adjusts the position of lens elements or the image sensor to maintain stability and minimize blurring. By enhancing the camera's ability to compensate for shake or jitter, optical image stabilization contributes to improved low-light performance, smoother video recording, and overall better image quality, providing users with the means to capture crisp and steady shots even in challenging conditions.

For example and as is shown in FIG. 14, optical device 404 may be a mirror assembly configured to bend/fold optical path 446. Such a configuration may allow for the use of longer optical paths when space is at a premium (such as within a cell phone). Assume that central object 448 is shifting due to e.g., movement of the camera. Accordingly, the MEMS imaging actuator assembly (e.g., MEMS imaging actuator assembly 350) may rotate optical device 404 along the Z-axis (clockwise in this example) to properly position central object 448 within lens assembly 300 and optoelectronic device 26 (as shown in FIG. 15).

Referring also to FIG. 16, the one or more multi-morphic thin film actuator assemblies (e.g., one or more multi-morphic thin film actuator assemblies 358, 360, 362, 364) may be configured in an undulating (i.e., zig-zag) fashion as opposed to a rectangular fashion (as originally shown in FIGS. 9-10). Additionally and depending upon the design criteria, the motion control assemblies (e.g., motion control assemblies 378, 380, 382, 384 as shown in FIG. 9) may be more robust than as originally shown in FIG. 12, as they are shown in FIG. 16 to include a dozen cantilever assemblies.

The above-described multi-morphic thin film actuator assemblies (e.g., one or more multi-morphic thin film actuator assemblies 358, 360, 362, 364) and/or the one or more multi-morphic/mono-morphic thin film assemblies (e.g., one or more multi-morphic/mono-morphic thin film assemblies 396, 398, 400, 402) may be controlled via a feedback loop (e.g., feedback loop 450). Specifically, the feedback loop (e.g., feedback loop 450) may monitor the position of the optical device (e.g., optical device 404) via feedback signals (e.g., feedback signals 452) and provide control signals (e.g., control signals 454) to the tip-tilt displacement assembly (e.g., tip-tilt displacement assembly 356) to adjust the position of the optical device (e.g., optical device 404) is multiple axes (e.g., the X-axis and/or the Z-axis) in response to feedback signals 452.

In Optical Image Stabilization (OIS) systems, feedback loops (e.g., feedback loop 450) are integral to enhancing the performance of image stabilization mechanisms in cameras and other optical devices. OIS aims to counteract unwanted motion and vibrations, ensuring clearer and sharper images or videos. The system typically includes motion sensors, such as accelerometers or gyroscopes, to detect any unintended movements. These sensors generate feedback signals (e.g., feedback signals 452) based on the detected motion, and this information is then fed into a control system (e.g., tip-tilt displacement assembly 356). In a negative feedback loop, the control system (e.g., tip-tilt displacement assembly 356) processes the input signals (e.g., control signals 454) and calculates the necessary adjustments to the optical elements optical device (e.g., optical device 404). These adjustments are aimed at compensating for the detected motion, effectively stabilizing the image. As the stabilized image is captured, the system continues to monitor for any residual motion, creating a continuous loop of detection and correction.

Specifically, in order to make the whole assembly simpler and lower cost without using external/additional sensing mechanism, the position/displacement feedback signals (e.g., feedback signals 452) may be provided by measuring the change in dielectric constant of the piezoelectric material layer (e.g., piezoelectric layer 366). This may be accomplished by:
measuring the capacitances between the electrodes (e.g., one or more electrodes 368, 370) on the piezoelectric material layer (e.g., piezoelectric layer 366), or
measuring the change in resistivity of the structural layer (e.g., structural layer 372) in the piezoelectric multi-morphic thin films if a piezoresistive material (e.g., polysilicon) is used for the structural layer.

### General:

In general, the various operations of method described herein may be accomplished using or may pertain to components or features of the various systems and/or apparatus with their respective components and subcomponents, described herein.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of example block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

While various embodiments of the present disclosure have been described above, it should be understood that they have been presented by way of example only, and not of limitation. Likewise, the various diagrams may depict an example architectural or other configuration for the disclosure, which is done to aid in understanding the features and functionality that can be included in the disclosure. The disclosure is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present disclosure. Additionally, with regard to flow diagrams, operational descriptions and method claims, the order in which the steps are presented herein shall not mandate that various embodiments be implemented to perform the recited functionality in the same order unless the context dictates otherwise.

Although the disclosure is described above in terms of various example embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosure, whether or not such embodiments are described and whether or not such features are presented as being a part of a described embodiment. Thus, the breadth and scope of the present disclosure should not be limited by any of the above-described example embodiments, and it will be understood by those skilled in the art that various changes and modifications to the previous descriptions may be made within the scope of the claims.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

A number of implementations have been described. Having thus described the disclosure of the present application in detail and by reference to embodiments thereof, it will be apparent that modifications and variations are possible without departing from the scope of the disclosure defined in the appended claims.

What is claimed is:

1. A MEMS imaging actuator assembly comprising:
a first structural assembly;
a second structural assembly; and
a tip-tilt displacement assembly, configured to position the first structural assembly with respect to the second structural assembly, including:
one or more multi-morphic thin film actuator assemblies, and
one or more motion control assemblies;
wherein one of the structural assemblies is configured to mount an optical device.

2. The MEMS imaging actuator assembly of claim 1 wherein the first structural assembly is rigidly affixed and the second structural assembly is configured to be displaceable by the tip-tilt displacement assembly with respect to the first structural assembly.

3. The MEMS imaging actuator assembly of claim 1 wherein the second structural assembly is rigidly affixed and the first structural assembly is configured to be displaceable by the tip-tilt displacement assembly with respect to the second structural assembly.

4. The MEMS imaging actuator assembly of claim 1 wherein the optical device is a mirror assembly.

5. The MEMS imaging actuator assembly of claim 1 wherein the optical device is an image sensor assembly.

6. The MEMS imaging actuator assembly of claim 1 wherein the first structural assembly includes:
one or more embedded snubber assemblies configured to interface with the second structural assembly and limit in-plane movement of the first structural assembly.

7. The MEMS imaging actuator assembly of claim 1 further comprising:
an outer frame assembly positioned proximate the second structural assembly.

8. The MEMS imaging actuator assembly of claim 7 further comprising:
one or more electrically conductive flexures configured to electrically couple the outer frame assembly and the second structural assembly.

9. The MEMS imaging actuator assembly of claim 1 wherein the one or more multi-morphic thin film actuator assemblies includes:
a piezoelectric layer.

10. The MEMS imaging actuator assembly of claim 1 wherein the one or more multi-morphic thin film actuator assemblies includes:
one or more electrodes positioned proximate the piezoelectric layer.

11. The MEMS imaging actuator assembly of claim 1 wherein the one or more multi-morphic thin film actuator assemblies includes:
a structural layer.

12. The MEMS imaging actuator assembly of claim 1 wherein one of the structural assemblies includes:
one or more glue pads for affixing the optical device.

13. The MEMS imaging actuator assembly of claim 1 wherein the tip-tilt displacement assembly is configured to allow rotation of the optical device around two axes.

14. The MEMS imaging actuator assembly of claim 1 wherein the MEMS imaging actuator is configured to effectuate one or more of OIS functionality and autofocus functionality.

15. The MEMS imaging actuator assembly of claim 1 further comprising:
a feedback loop configured to process feedback signals that are indicative of a change in dielectric constant of a piezoelectric layer within the one or more multi-morphic thin film actuator assemblies.

16. A MEMS imaging actuator assembly comprising:
a first structural assembly;
a second structural assembly; and
a tip-tilt displacement assembly, configured to position the first structural assembly with respect to the second structural assembly, including:
one or more multi-morphic thin film actuator assemblies, and
one or more motion control assemblies;
wherein one of the structural assemblies is configured to mount an optical device; and
wherein the optical device is a mirror assembly.

17. The MEMS imaging actuator assembly of claim 16 wherein the first structural assembly is rigidly affixed and the second structural assembly is configured to be displaceable by the tip-tilt displacement assembly with respect to the first structural assembly.

18. The MEMS imaging actuator assembly of claim 16 wherein the second structural assembly is rigidly affixed and the first structural assembly is configured to be displaceable by the tip-tilt displacement assembly with respect to the second structural assembly.

19. The MEMS imaging actuator assembly of claim 16 wherein the first structural assembly includes:
one or more embedded snubber assemblies configured to interface with the second structural assembly and limit in-plane movement of the first structural assembly.

20. The MEMS imaging actuator assembly of claim 16 further comprising:
a feedback loop configured to process feedback signals that are indicative of a change in dielectric constant of a piezoelectric layer within the one or more multi-morphic thin film actuator assemblies.

21. A MEMS imaging actuator assembly comprising:
a first structural assembly;
a second structural assembly; and
one or more embedded snubber assemblies configured to interface with the second structural assembly and limit in-plane movement of the first structural assembly;
a tip-tilt displacement assembly, configured to position the first structural assembly with respect to the second structural assembly, including:
one or more multi-morphic thin film actuator assemblies, and
one or more motion control assemblies;
wherein one of the structural assemblies is configured to mount an optical device; and
wherein the optical device is a mirror assembly.

22. The MEMS imaging actuator assembly of claim 21 wherein the first structural assembly is rigidly affixed and the second structural assembly is configured to be displaceable by the tip-tilt displacement assembly with respect to the first structural assembly.

23. The MEMS imaging actuator assembly of claim 21 wherein the second structural assembly is rigidly affixed and the first structural assembly is configured to be displaceable by the tip-tilt displacement assembly with respect to the second structural assembly.

24. The MEMS imaging actuator assembly of claim 21 further comprising:
an outer frame assembly positioned proximate the second structural assembly.

25. The MEMS imaging actuator assembly of claim 24 further comprising:
one or more electrically conductive flexures configured to electrically couple the outer frame assembly and the second structural assembly.

26. The MEMS imaging actuator assembly of claim 21 wherein the one or more multi-morphic thin film actuator assemblies includes:
a piezoelectric layer;
one or more electrodes positioned proximate the piezoelectric layer; and
a structural layer.

27. The MEMS imaging actuator assembly of claim 21 wherein the MEMS imaging actuator is configured to effectuate one or more of OIS functionality and autofocus functionality.

28. The MEMS imaging actuator assembly of claim 21 further comprising:
a feedback loop configured to process feedback signals that are indicative of a change in dielectric constant of a piezoelectric layer within the one or more multi-morphic thin film actuator assemblies.
